(19) United States
(12) Patent Application Publication
(10) Pub. No.: US 2006/0046387 A1
(43) Pub. Date: Mar. 2, 2006

(54) Flash memory devices having an alternately arrayed inter-gate dielectric layer and methods of fabricating the same

(76) Inventors: Han-Mei Choi, Seoul (KR); Jong-Cheol Lee, Seoul (KR); Seung-Hwan Lee, Seoul (KR); Dae-Sik Choi, Seoul (KR); Ki-Yeon Park, Gyeonggi-do (KR); Young-sun Kim, Gyeonggi-do (KR); Cha-Young Yoo, Gyeonggi-do (KR); Sung-Tae Kim, Seoul (KR)

Correspondence Address: MYERS BIGEL SIBLEY & SAJOVEC, PO BOX 37428, RALEIGH, NC, 27627, US

(21) Appl. No.: 11/180,172

(22) Filed: Jul. 13, 2005

(30) Foreign Application Priority Data
Aug. 26, 2004 (KR) 10-2004-67639

(51) Int. Cl. H01L 21/336

(52) U.S. Cl. 438/257

(57) ABSTRACT

Flash memory devices include a semiconductor substrate having an active region. A gate pattern on the active region includes a floating gate pattern and a control gate pattern with an inter-gate dielectric layer pattern therebetween. The inter-gate dielectric layer pattern includes a plurality of hafnium oxide layers and a plurality of aluminum oxide layers, ones of which are alternately arrayed.

### CROSS-REFERENCE TO RELATED APPLICATION

This patent application is related to and claims priority from Korean Patent Application No. 10-2004-67639, filed Aug. 26, 2004, the contents of which are hereby incorporated by reference in their entirety.

### BACKGROUND OF THE INVENTION

The present invention relates to semiconductor devices and methods of fabricating the same and, more particularly, to flash memory devices and methods of fabricating the same.

Flash memory devices are a type of memory device that is designed to retain stored data even when the power supply to the device is interrupted. Flash memory devices typically include a floating gate capable of accumulating charges in a metal oxide semiconductor (MOS) transistor structure.

A flash memory device is generally formed to include a thin gate oxide layer, referred to as a tunnel insulating layer, on a semiconductor substrate. A floating gate pattern made of a conductive material is formed on the gate oxide layer. An inter-gate dielectric layer is disposed on the floating gate pattern to form a control gate pattern. Accordingly, the floating gate is generally electrically insulated from the semiconductor substrate and the control gate pattern by the tunnel insulating layer and the inter-gate dielectric layer. In such a device case, an oxide-nitride-oxide (ONO) structure, such as SiO₂—Si₃N₄—SiO₂, is employed for the inter-gate dielectric layer.

An inter-gate dielectric layer having an ONO structure typically has a low dielectric constant. As there is a limit to decreasing an equivalent oxide thickness in such a device. In order to address this limitation, it is known to use a metal oxide having a dielectric constant of 8 or more as the inter-gate dielectric layer.

Dielectric constants and energy band gaps of SiO₂, Si₃N₄ and metal oxide are listed in Table 1 below.

TABLE 1

| Inter-gate | Dielectric | Energy band |
|---|---|---|
| dielectric layer | constant | gap (eV) |
| SiO₂ | 3.9 | 8.9 |
| Si₃N₄ | 7 | 5.1 |
| Al₂O₃ | 9 | 8.7 |
| HfO₂ | 20 | 5.7 |

The SiO₂ layer of an ONO structure, as listed in of Table 1, has a dielectric constant of 3.9 and an energy band gap of 8.9 eV, and the Si₃N₄ layer has a dielectric constant of 7 and an energy band gap of 5.1 eV.

The ONO (SiO₂—Si₃N₄—SiO₂) layer describe above, thus, has a low dielectric constant so that it may not meet the performance requirements for high density devices. In other words, it may be difficult to reduce the thickness of the inter-gate dielectric layer due to its low dielectric constant. As a result, there is generally a limit in applying the ONO gate dielectric layer to high speed and high density devices.

An aluminum oxide layer (Al₂O₃) having a dielectric constant of 8 or more typically has a good energy band gap of 8.7 eV. However, it may not have a sufficiently high dielectric constant. An HfO₂ layer generally has a dielectric constant of 20 so that it may reduce the equivalent oxide thickness by means of the high dielectric constant. However, it may cause leakage current degradation to occur due to its typically low energy band gap of 5.7 eV. Accordingly, in order to address the problems of the aluminum oxide layer having a low dielectric constant and the hafnium oxide layer having a low energy band gap, a dielectric layer may be formed of a combination of a hafnium oxide layer and a aluminum oxide layer.

A multilayer dielectric stack with alternating layers of a high-k material and an interposing material is described in U.S. Pat. No. 6,407,435. More particularly, a multilayer dielectric stack is illustrated as a dielectric layer between between a channel region and a gate electrode of an MOS transistor gate structure. The high-k dielectric layers may be a metal oxide of zirconium or hafnium and the interposing material layer may be an amorphous aluminum oxide, aluminum nitride or silicon nitride.

Leakage current characteristics of a hafnium oxide layer typically become degraded when the hafnium oxide layer is crystallized as compared to its amorphous state. In addition, when an aluminum oxide layer is deposited at a high temperature on a hafnium oxide layer, the hafnium oxide layer below the aluminum oxide layer is typically crystallized due to the high temperature, which generally causes the leakage current characteristics to be degraded.

### SUMMARY OF THE INVENTION

Embodiments of the present invention provide flash memory devices including a semiconductor substrate having an active region. A gate pattern on the active region includes a floating gate pattern and a control gate pattern with an inter-gate dielectric layer pattern therebetween. The inter-gate dielectric layer pattern includes a plurality of hafnium oxide layers and a plurality of aluminum oxide layers, ones of which are alternately arrayed.

In other embodiments of the present invention, the inter-gate dielectric layer has a thickness of about 100 to about 500 Å. A thickness ratio of a layer of the hafnium oxide layers to a layer of the aluminum oxide layers may be in a range from about 1:2 to about 5:1. The layer of the hafnium oxide layers may have a thickness of about 0.5 to about 10 Å. The layer of the aluminum oxide layers may have a thickness of about 0.5 to about 5 Å. The hafnium oxide layers may have an amorphous structure.

In further embodiments of the present invention, a SiO and/or AlO layer is provided between the floating gate pattern and the inter-gate dielectric layer pattern and/or between the control gate pattern and the inter-gate dielectric layer pattern. The SiO and/or AlO layer may have a thickness of no more than about 10 Å.

In other embodiments of the present invention, the floating gate pattern includes a polysilicon layer, a metal nitride layer and/or a stacked layer including a polysilicon layer and a metal nitride layer. The metal nitride layer may be one or more of a tungsten nitride layer, a titanium nitride layer and/or a tantalum nitride layer. The control gate pattern may be a sequentially stacked polysilicon layer, metal nitride layer and tungsten layer or a sequentially stacked metal nitride layer and tungsten layer. The metal nitride layer may be one or more of a tungsten nitride layer, a titanium nitride layer and/or a tantalum nitride layer.

In yet further embodiments of the present invention, the semiconductor substrate includes a plurality of active regions. The gate pattern is a plurality of gate patterns that cross over the active regions.

In other embodiments of the present invention, methods of fabricating a flash memory device include providing a semiconductor substrate having an active region. A floating gate pattern is formed on the active region. An inter-gate dielectric layer pattern is formed on the floating gate pattern. Forming the inter-gate dielectric layer pattern includes alternately and repeatedly forming a hafnium oxide layer and an aluminum oxide layer at least twice. A control gate pattern is formed on the inter-gate dielectric layer pattern.

In further embodiments of the present invention, forming the inter-gate dielectric layer pattern includes forming the inter-gate dielectric layer pattern by one or more of an atomic layer deposition (ALD) method, a plasma enhanced atomic layer deposition (PEALD) method, a physical vapor deposition (PVD) method and/or a chemical vapor deposition (CVD) method. Forming the inter-gate dielectric layer pattern may include forming the inter-gate dielectric layer pattern at a temperature of no more than about 900° C.

In yet other embodiments of the present invention, a SiO and/or AlO layer is formed between the floating gate pattern and the inter-gate dielectric layer pattern and/or a SiO and/or AlO layer is formed between the control gate pattern and the inter-gate dielectric layer pattern. The SiO and/or AlO layer may be formed to a thickness of no more than about 10 Å.

In yet further embodiments of the present invention, the floating gate pattern is formed of a polysilicon layer, a metal nitride layer or a stacked layer including a polysilicon layer and a metal nitride layer. The metal nitride layer may be one or more of a tungsten nitride layer, a titanium nitride layer and/or a tantalum nitride layer. The metal nitride layer may be formed using one or more of an atomic layer deposition (ALD) method, a sequential flow deposition (SFD) method, a chemical vapor deposition (CVD) method and/or a physical vapor deposition (PVD) method.

In other embodiments of the present invention, the control gate pattern is formed of a sequentially stacked polysilicon layer, metal nitride layer and tungsten layer or a sequentially stacked metal nitride layer and tungsten layer. The metal nitride layer may be formed of one or more of a tungsten nitride layer, a titanium nitride layer and/or a tantalum nitride layer. The metal nitride layer may be formed using one or more of an atomic layer deposition (ALD) method, a sequential flow deposition (SFD) method, a chemical vapor deposition (CVD) method and/or a physical vapor deposition (PVD) method.

In further embodiments of the present invention, preparing a semiconductor substrate includes preparing a semiconductor substrate including a plurality of active regions. The floating gate pattern, inter-gate dielectric layer pattern and control gate pattern define a gate pattern. A plurality of gate patterns are formed crossing the active regions.

In yet further embodiments of the present invention a flash memory device includes a semiconductor substrate having active regions. A plurality of gate patterns crossing over the active regions are disposed on the semiconductor substrate. The gate patterns have a floating gate pattern, an inter-gate dielectric layer pattern, and a control gate pattern, which are sequentially stacked. In this case, the inter-gate dielectric layer pattern is disposed by alternately and repeatedly depositing a hafnium oxide layer and an aluminum oxide layer at least twice.

The floating gate pattern may be one layer selected from a group consisting of a polysilicon layer and a metal nitride layer, or a stacked layer thereof. The metal nitride layer may be at least one layer selected from a group consisting of a tungsten nitride layer (WN), a titanium nitride layer (TiN), and a tantalum nitride layer (TaN). The control gate pattern may be a polysilicon layer, a metal nitride layer and a tungsten layer that are sequentially stacked, or a metal nitride layer and a tungsten layer that are sequentially stacked. The metal nitride layer may be at least one layer selected from a group consisting of a tungsten nitride layer, a titanium nitride layer and a tantalum nitride layer.

In yet other embodiments of the present invention, a method of fabricating a flash memory device includes preparing a semiconductor substrate having active regions. A plurality of gate patterns is formed on the semiconductor substrate to cross over the active regions. The gate patterns are formed to have a floating gate pattern, an inter-gate dielectric layer pattern, and a control gate pattern, which are sequentially stacked. In this case, the inter-gate dielectric layer pattern is formed by alternately and repeatedly depositing a hafnium oxide layer and an aluminum oxide layer at least twice.

The inter-gate dielectric layer pattern may be formed using at least one method selected from a group consisting of an atomic layer deposition (ALD) method, a plasma enhanced atomic layer deposition (PEALD) method, a physical vapor deposition (PVD) method, and a chemical vapor deposition (CVD) method. The floating gate pattern may be formed of one layer selected from a group consisting of a polysilicon layer and a metal nitride layer, or a stacked layer thereof. The metal nitride layer may be formed at least one layer selected from a group consisting of a tungsten nitride layer (WN), a titanium nitride layer (TiN), and a tantalum nitride layer (TaN). The metal nitride layer may be formed using at least one method selected from a group consisting of an ALD method, a sequential flow deposition (SFD) method, a CVD method, and a PVD method. The control gate pattern may be formed of a polysilicon layer, a metal nitride layer and a tungsten layer that are sequentially stacked, or a metal nitride layer and a tungsten layer that are sequentially stacked. The metal nitride layer may be formed at least one layer selected from a group consisting of a tungsten nitride layer, a titanium nitride layer and a tantalum nitride layer. The metal nitride layer may be formed using at least one method selected from a group consisting of an ALD method, an SFD method, a CVD method, and a PVD method.

### BRIEF DESCRIPTION OF THE DRAWINGS

FIG. 1 is a layout view of a NOR-type flash memory device according to some embodiments of the present invention.

FIG. 2 is a cross-sectional view of the NOR-type flash memory device of FIG. 1 taken along the line I-I′ in FIG. 1.

FIGS. 3A to 3C are cross-sectional views illustrating methods of fabricating a flash memory device according to some embodiments of the present invention, taken from the view of the line I-I′ in FIG. 1.

FIG. 4 is a graph illustrating a crystallinity analysis result for an inter-gate dielectric layer according to some embodiments of the present invention.

FIG. 5 is a graph illustrating equivalent oxide thickness for an inter-gate dielectric layer according to some embodiments of the present invention.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

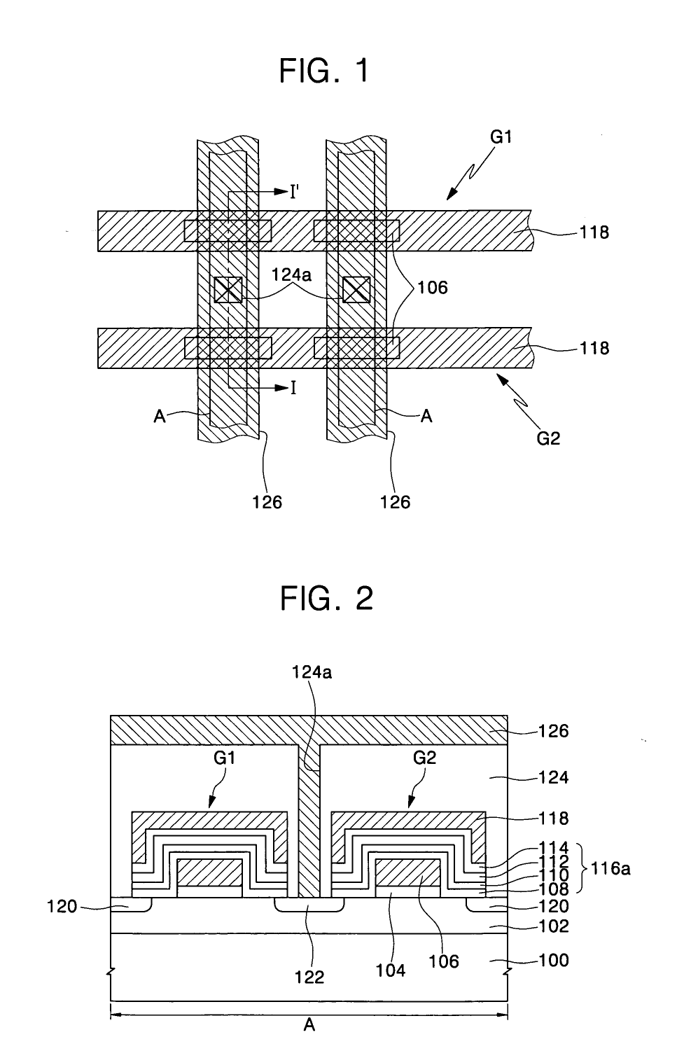

Various embodiments of the present invention will now be described with reference to the figures. FIG. 1 is a layout view of a NOR-type flash memory device according to some embodiments of the present invention. FIG. 2 is a cross-sectional view of the NOR-type flash memory device of FIG. 1 taken along the line I-I′ in FIG. 1.

Referring now to the embodiments of FIGS. 1 and 2, a well region 102 is disposed in a semiconductor substrate 100. A plurality of cell active regions A, isolated by an isolation layer (not shown), are located in the well region 102.

A plurality of cell gate patterns G1 and G2 are arranged to cross over the cell active regions A. Each of the cell gate patterns G1 and G2 in the embodiments of FIGS. 1 and 2 has a tunnel insulating layer 104, a floating gate pattern 106, an inter-gate dielectric layer pattern 116a, and a control gate pattern 118, which are sequentially stacked. For the illustrated embodiments of FIGS. 1 and 2, the inter-gate dielectric layer pattern 116a has a structure including a hafnium oxide layer (HfO) and an aluminum oxide layer (AlO) that are alternately and repeatedly deposited at least twice. An aluminum oxide layer or a hafnium oxide layer may be disposed at a region in contact with the floating gate pattern 106. In a similar way, the aluminum oxide layer or the hafnium oxide layer may be disposed at a region in contact with the control gate pattern 118. For example, the inter-gate dielectric layer pattern 116a may include a hafnium oxide layer 108, an aluminum oxide layer 110, a hafnium oxide layer 112, and an aluminum oxide layer 114 that are sequentially stacked. In other embodiments, the inter-gate dielectric layer pattern 116a may include, sequentially from a lowest layer, an aluminum oxide layer, a hafnium oxide layer, an aluminum oxide layer, and a hafnium oxide layer.

The inter-gate dielectric layer pattern 116a in some embodiments has a thickness of about 100 to about 500 Å. A stacked thickness ratio of each layer of the hafnium oxide layers 108 and 112 and the aluminum oxide layers 110 and 114 may be about 1:2 to 5:1. Each of the hafnium oxide layers 108 and 112 may have a thickness of about 0.5 to 10 Å. The hafnium oxide layers 108 and 112 may have an amorphous structure. Each of the aluminum oxide layers 110 and 114 may have a thickness of about 0.5 to 5 Å. This thickness range may allow the aluminum oxide layers 110 and 114 to have a low equivalent oxide layer thickness.

A SiO and/or AlO layer having a large energy band gap may also be positioned between the floating gate pattern 106 and the inter-gate dielectric layer pattern 116a and/or between the control gate pattern 118 and the inter-gate dielectric layer pattern 116a. The SiO and/or AlO layer so positioned may be included to increase a barrier height of the leakage current. The SiO and/or AlO layer so positioned may has a thickness of about 10 Å or less.

In some embodiments of the present invention, the floating gate pattern 106 is a polysilicon layer. In other embodiments, the floating gate pattern 106 is a sequentially stacked polysilicon layer and metal nitride layer. In yet other embodiments, the floating gate pattern 106 is a metal nitride layer. The metal nitride layer may be at least one material layer selected from a group consisting of a tungsten nitride layer, a titanium nitride layer, and a tantalum nitride layer.

The control gate pattern 118 may be a sequentially stacked polysilicon layer, metal nitride layer and tungsten layer. The control gate pattern 118 may also be a sequentially stacked metal nitride layer and tungsten layer. The metal nitride layer may be at least one material layer selected from a group consisting of a tungsten nitride layer, a titanium nitride layer, and a tantalum nitride layer.

As further seen in the embodiments of FIGS. 1 and 2, source and drain regions 120 and 122 are disposed in the semiconductor substrate 100 at both sides of the cell gate patterns G1 and G2. An interlayer insulating layer 124 is disposed on the semiconductor substrate 100 in the region including the source and drain regions 120 and 122. Bit line contact holes 124a penetrating the interlayer insulating layer 124 are disposed between the gate patterns G1 and G2. Bit lines 126 are formed on the inter-insulating layer 124 so as to effectively fill the bit line contact holes 124a. The bit lines 126 are, thus, in electrical contact with one of the source and/or drain regions 120 and 122 through the bit line contact holes 124a.

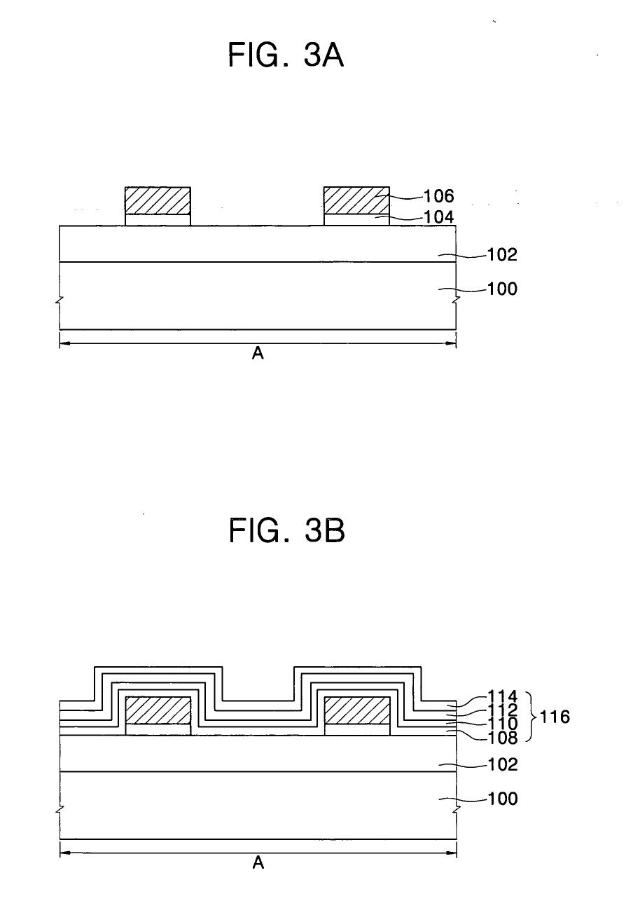

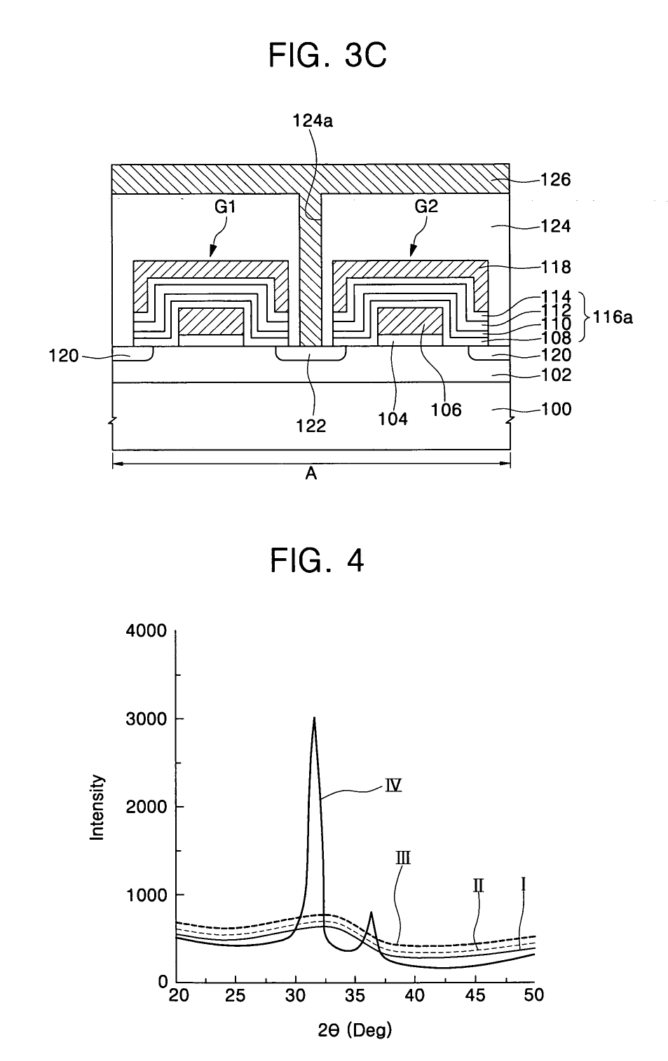

FIGS. 3A to 3C are cross-sectional views illustrating methods of manufacturing a flash memory device according to some embodiments of the present invention. The cross-sectional views of FIGS. 3A to 3C are taken along the line I-I′ in FIG. 1.

Referring first to FIG. 3A, the well region 102 is formed in the semiconductor substrate 100, for example, by an ion implantation process. The plurality of cell active regions A isolated by an isolation layer (not shown) are formed in the semiconductor substrate 100 including the well region 102. A tunnel oxide layer 104 is formed on the semiconductor substrate. The tunnel oxide layer 104 may be formed, for example, using a thermal oxidation process.

A floating gate pattern 106 is shown formed on the tunnel oxide layer 104. The floating gate pattern 106 in some embodiments is formed from a polysilicon layer. In other embodiments, the floating gate pattern 106 is formed from a sequentially stacked polysilicon layer and metal nitride layer. In yet other embodiments, the floating gate pattern 106 is formed from a metal nitride layer. The metal nitride layer may be at least one layer selected from a group consisting of a tungsten nitride layer (WN), a titanium nitride layer (TiN), and a tantalum nitride layer (TaN). The metal nitride layer may be formed using, for example, atomic layer deposition (ALD), sequential flow deposition (SFD), chemical vapor deposition (CVD) and/or physical vapor deposition (PVD).

Referring next to FIG. 3B, an inter-gate dielectric layer 116 is formed on the floating gate pattern 106. In the illustrated embodiments of FIG. 3B, the inter-gate dielectric layer 116 is formed by alternately and repeatedly depositing a hafnium oxide layer (HfO) and an aluminum oxide layer(AlO) at least twice. Either aluminum oxide layer or a hafnium oxide layer may be formed first at a region in contact with the floating gate pattern 106. Similarly, either an aluminum oxide layer or a hafnium oxide layer may be used for the layer in contact with the control gate layer 118 to be formed later (FIG. 3C). In some embodiments, the inter-gate dielectric layer 116 is formed to have a structure, building from the floating gate pattern 106, of a hafnium oxide layer 108, an aluminum oxide layer 110, a hafnium oxide layer 112, and an aluminum oxide layer 114, which are sequentially stacked as shown in FIG. 3B. In other embodiments, the inter-gate dielectric layer 116 may be formed to have a structure, building from the floating gate pattern 106, of an aluminum oxide layer, a hafnium oxide layer, an aluminum oxide layer, and a hafnium oxide layer, which are sequentially stacked. The hafnium oxide layers 108 and 112 may be formed in an amorphous structure to minimize the leakage current while the flash memory device is driven in use.

The inter-gate dielectric layer 116 may be formed to a thickness of about 100 to about 500 Å. Each layer of the hafnium oxide layers 108 and 112 and the aluminum oxide layers 110 and 114 may be formed to have a stacked thickness ratio of about 1:2 to about 5:1. Each of the hafnium oxide layers 108 and 112 in some embodiments may be formed to have a thickness of 20 Å or less, as crystallization may occur when the thickness exceeds 20 Å. In some embodiments, the thickness of each of the hafnium oxide layers 108 and 112 is about 0.5 to about 10 Å.

The aluminum oxide layers 110 and 114 in some embodiments of the present invention are each formed to have a thickness of about 20 Å or less, because an equivalent oxide layer thickness may otherwise become too large. In some embodiments, each of the aluminum oxide layers 110 and 114 is formed to a thickness of about 0.5 to about 5 Å.

The inter-gate dielectric layer 116 may be formed using one or more method such as atomic layer deposition (ALD), plasma enhanced atomic layer deposition (PEALD), physical vapor deposition (PVD) and/or chemical vapor deposition (CVD). The hafnium oxide layers 108 and 112 may be crystallized when the inter-gate dielectric layer 116 is deposited at a temperature of 900° C. or greater. Accordingly, in order to address this problem, in some embodiments of the present invention, the inter-gate dielectric layer 116 is formed at a temperature of no more than 900° C.

When the inter-gate dielectric layer 116 is formed, a SiO or AlO layer having a large energy band gap may also be formed between the floating gate pattern 106 and the inter-gate dielectric layer 116, which may increase a barrier height of the leakage current. The SiO or AlO layer in some embodiments is formed to a thickness of about 10 Åor less.

Referring now to FIG. 3C, a conductive layer (not shown) is formed above the inter-gate dielectric layer 116 that is patterned to form the control gate pattern 118. The conductive layer (control gate pattern 118) may be formed of a sequentially stacked polysilicon layer, metal nitride layer and tungsten layer and/or a sequentially stacked metal nitride layer and tungsten layer. The metal nitride layer may be formed of at least one layer selected from a group consisting of a tungsten nitride layer, a titanium nitride layer and a tantalum nitride layer. The metal nitride layer may be formed using at least one method selected from a group consisting of an ALD method, an SFD method, a CVD method, and a PVD method. Before the conductive layer is formed, a SiO or AlO layer having a large energy band gap may be formed between the inter-gate dielectric layer 116 and the conductive layer in order to increase a barrier height of the leakage current. The SiO or AlO layer may be formed to a thickness of about 10 Å or less.

The conductive layer and the inter-gate dielectric layer 116 may be patterned by photolithography and etching processes to form the inter-gate dielectric layer pattern 116a and the control gate pattern 118. As a result, cell gate patterns G1 and G2 having the tunnel insulating layer 104, the floating gate pattern 106, the inter-gate dielectric layer pattern 116a, and the control gate pattern 118 may be formed on the semiconductor substrate 100.

Source and drain regions 120 and 122 are formed in the semiconductor substrate, for example, using the cell gate patterns G1 and G2 as masks. An inter-insulating layer 124 is shown in the embodiments of FIG. 3C formed on the semiconductor substrate 100 to cover the cell gate patterns G1 and G2. Bit line contact holes 124a are formed to penetrate the inter-insulating layer 124 to expose one or more of the source and/or drain regions 120 and 122. Bit lines 126 are shown in the illustrated embodiments formed on the inter-insulating layer 124 so as to sufficiently fill the bit line contact holes 124a. The bit lines 126 may be formed on the inter-insulating layer 124 spaced apart from each other by a predetermined interval as shown in FIG. 1.

FIG. 4 is a graph illustrating a crystallinity analysis result for an inter-gate dielectric layer according to some embodiments of the present invention. The crystallinity analysis is performed using an X-ray diffraction (XRD) apparatus. The crystallinity analysis is performed on the inter-gate dielectric layer 116 of FIG. 3b. In particular, the hafnium oxide layer and the aluminum oxide layer in the inter-gate dielectric layer 116 for the illustrative results of FIG. 4 have a thickness ratio of 4:1.

Referring now to FIG. 4, the reference character “I” indicates the crystallinity analysis result for a hafnium oxide layer that has not been subjected to an annealing process. The hafnium oxide layer has an amorphous structure. Reference characters “II” and “III” indicate crystallinity analysis results for the hafnium oxide layer after annealing processes are performed on the inter-gate dielectric layer 116 at 750° C. and 850° C., respectively. In these cases, the hafnium oxide layer has an amorphous structure. The reference character “IV” indicates a crystallinity analysis result of the hafnium oxide layer after the annealing process is performed on the inter-gate dielectric layer 116 at 950° C. The hafnium oxide layer in this case has a crystalline structure after the annealing process is performed at 950° C. In other words, the inter-gate dielectric layer 116 includes a crystallized hafnium oxide layer as a result of carrying out the annealing process at 950° C. Accordingly, in some embodiments of the present invention, in order to maintain a hafnium oxide layer having an amorphous structure, the inter-gate dielectric layer 116 is formed at a temperature of 900° C. or less.

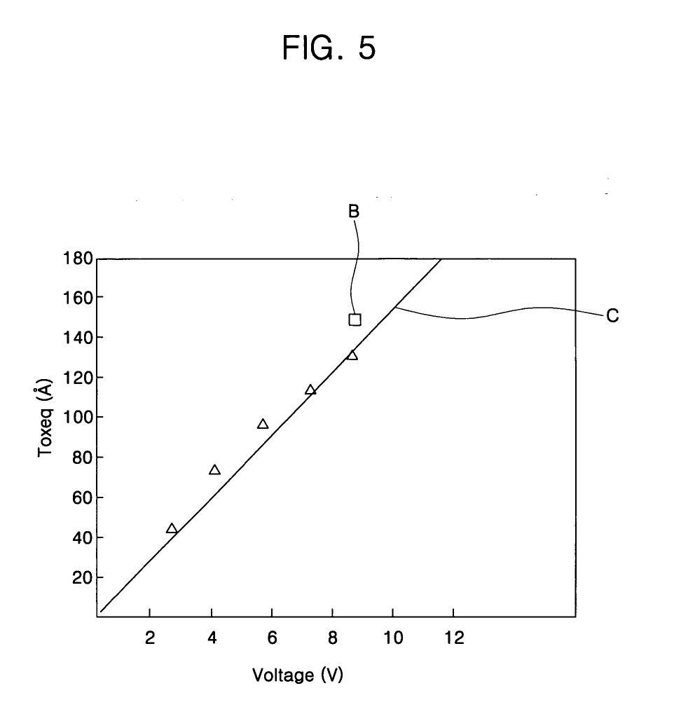

FIG. 5 is a graph illustrating equivalent oxide thickness of an inter-gate dielectric layer according to some embodiments of the present invention. The horizontal axis of the graph indicates voltages (V) applied between the semiconductor substrate 100 and the control gate pattern 118 of FIG. 2 and the vertical axis of the graph indicates equivalent oxide thickness (Å) when a leakage current of the inter-gate dielectric layer pattern 116a is about 10⁻¹⁵ A/cell in response to the applied voltages, respectively. The reference character “B” of the graph indicates an equivalent oxide thickness of a conventional ONO dielectric structure. The reference character “C” of the graph indicates a trend line of equivalent oxide thickness of the inter-gate dielectric layer pattern 116a of FIG. 2.

Referring now to FIG. 5, when the equivalent oxide thickness of the inter-gate dielectric layer pattern 116a are compared with those of the ONO dielectric layer, the inter-gate dielectric layer pattern 116a has a smaller equivalent oxide thickness, satisfying a leakage current of 10⁻¹⁵ A/cell at the same voltage as compared to that of the ONO dielectric layer. For example, the inter-gate dielectric layer pattern 116a may be expected based on the trend line, to have an equivalent oxide thickness of about 130 Å at a voltage of 9.0V. In contrast, the ONO dielectric layer has an equivalent oxide thickness of about 150 Å at a voltage of 9.0V. In conclusion, it may be seen from the graph that the equivalent oxide thickness of the inter-gate dielectric layer pattern 116a required for minimizing the leakage current of the flash memory device may be decreased relative to that of the ONO dielectric layer.

As discussed above, some embodiments of the present invention provide a method of forming an inter-gate dielectric layer pattern by alternately and repeatedly depositing a hafnium oxide layer and an aluminum oxide layer at least twice in order to minimize the leakage current while the flash memory device is driven. Accordingly, the flash memory device and method of fabricating the same in some embodiments may allow the hafnium oxide layer to have an amorphous structure, which may lead to a reduction in the leakage current of the inter-gate dielectric layer.

As will be understood from the discussion above, some embodiments of the present invention are related to a flash memory device having an inter-gate dielectric layer with a high-k dielectric characteristic and methods of forming the same. The inter-gate dielectric layer may be capable of reducing a thickness of the equivalent oxide layer and preventing the leakage current degradation.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A flash memory device, comprising:
a semiconductor substrate having an active region; and
a gate pattern on the active region, the gate pattern including a floating gate pattern and a control gate pattern with an inter-gate dielectric layer pattern therebetween, wherein the inter-gate dielectric layer pattern includes a plurality of hafnium oxide layers and a plurality of aluminum oxide layers ones of which are alternately arrayed.

2. The flash memory device of claim 1, wherein the inter-gate dielectric layer has a thickness of about 100 to about 500 Å.

3. The flash memory device of claim 1, wherein a thickness ratio of a layer of the hafnium oxide layers to a layer of the aluminum oxide layers is in a range from about 1:2 to about 5:1.

4. The flash memory device of claim 3, wherein the layer of the hafnium oxide layers has a thickness of about 0.5 to about 10 Å.

5. The flash memory device of claim 3, wherein the layer of the aluminum oxide layers has a thickness of about 0.5 to about 5 Å.

6. The flash memory device of claim 1, wherein the hafnium oxide layers have an amorphous structure.

7. The flash memory device of claim 1, further comprising a SiO and/or AlO layer between the floating gate pattern and the inter-gate dielectric layer pattern and/or between the control gate pattern and the inter-gate dielectric layer pattern.

8. The flash memory device of claim 7, wherein the SiO and/or AlO layer has a thickness of no more than about 10 Å.

9. The flash memory device of claim 1, wherein the floating gate pattern comprises a polysilicon layer, a metal nitride layer and/or a stacked layer including a polysilicon layer and a metal nitride layer.

10. The flash memory device of claim 9, wherein the metal nitride layer comprises a tungsten nitride layer, a titanium nitride layer and/or a tantalum nitride layer.

11. The flash memory device of claim 1, wherein the control gate pattern comprises a sequentially stacked polysilicon layer, metal nitride layer and tungsten layer or a sequentially stacked metal nitride layer and tungsten layer.

12. The flash memory device of claim 11, wherein the metal nitride layer comprises a tungsten nitride layer, a titanium nitride layer and/or a tantalum nitride layer.

13. The flash memory device of claim 1, wherein:
the semiconductor substrate includes a plurality of active regions; and
the gate pattern comprises a plurality of gate patterns that cross over the active regions.

14. A method of fabricating a flash memory device, the method comprising:
providing a semiconductor substrate having an active region;
forming a floating gate pattern on the active region;
forming an inter-gate dielectric layer pattern on the floating gate pattern, including alternately and repeatedly forming a hafnium oxide layer and an aluminum oxide layer at least twice; and
forming a control gate pattern on the inter-gate dielectric layer pattern.

15. The method of claim 14, wherein the inter-gate dielectric layer pattern is formed to a thickness of about 100 to about 500 Å.

16. The method of claim 14, wherein a thickness ratio of a layer of the hafnium oxide layers to a layer of the aluminum oxide layers is in a range from about 1:2 to about 5:1.

17. The method of claim 16, wherein the layer of the hafnium oxide layers is formed to have a thickness of about 0.5 to about 10 Å.

18. The method of claim 16, wherein the layer of the aluminum oxide layers is formed to have a thickness of about 0.5 to about 5 Å.

19. The method of claim 14, wherein the hafnium oxide layers are formed to have an amorphous structure.

20. The method of claim 14, wherein forming the inter-gate dielectric layer pattern comprises forming the inter-gate dielectric layer pattern by an atomic layer deposition (ALD) method, a plasma enhanced atomic layer deposition (PEALD) method, a physical vapor deposition (PVD) method and/or a chemical vapor deposition (CVD) method.

21. The method of claim 14, wherein forming the inter-gate dielectric layer pattern comprise forming the inter-gate dielectric layer pattern at a temperature of no more than about 900° C.

22. The method of claim 14, further comprising forming a SiO and/or AlO layer between the floating gate pattern and the inter-gate dielectric layer pattern and/or forming a SiO and/or AlO layer between the control gate pattern and the inter-gate dielectric layer pattern.

23. The method of claim 22, wherein the SiO and/or AlO layer is formed to a thickness of no more than about 10 Å.

24. The method of claim 14, wherein the floating gate pattern is formed of a polysilicon layer, a metal nitride layer or a stacked layer including a polysilicon layer and a metal nitride layer.

25. The method of claim 24, wherein the metal nitride layer comprises a tungsten nitride layer, a titanium nitride layer and/or a tantalum nitride layer.

26. The method of claim 25, wherein the metal nitride layer is formed using an atomic layer deposition (ALD) method, a sequential flow deposition (SFD) method, a chemical vapor deposition (CVD) method and/or a physical vapor deposition (PVD) method.

27. The method of claim 14, wherein the control gate pattern is formed of a sequentially stacked polysilicon layer, metal nitride layer and tungsten layer or a sequentially stacked metal nitride layer and tungsten layer.

28. The method of claim 27, wherein the metal nitride layer is formed of a tungsten nitride layer, a titanium nitride layer and/or a tantalum nitride layer.

29. The method of claim 28, wherein the metal nitride layer is formed using an atomic layer deposition (ALD) method, a sequential flow deposition (SFD) method, a chemical vapor deposition (CVD) method and/or a physical vapor deposition (PVD) method.

30. The method of claim 14 wherein preparing a semiconductor substrate comprises preparing a semiconductor substrate including a plurality of active regions and wherein the floating gate pattern, inter-gate dielectric layer pattern and control gate pattern define a gate pattern and wherein the method further comprises forming a plurality of gate patterns crossing the active regions.
